(19) United States
(12) Patent Application Publication
(10) Pub. No.: US 2024/0022044 A1
(43) Pub. Date: Jan. 18, 2024

(54) Semiconductor Laser and Method of Producing a Semiconductor Laser

(71) Applicant: ams-OSRAM International GmbH, Regensburg (DE)

(72) Inventors: Hubert Halbritter, Dietfurt (DE); Bruno Jentzsch, Regensburg (DE); Christian Lauer, Pettendorf (DE); Peter Fuchs, Regensburg (DE)

(21) Appl. No.: 18/253,256

(22) PCT Filed: Nov. 19, 2021
(86) PCT No.: PCT/EP2021/082290

§ 371 Date: May 17, 2023

(30) Foreign Application Priority Data
Dec. 11, 2020 (DE) 10 2020 133 174.6

(51) Int. Cl. H01S 5/10; H01S 5/02255; H01S 5/028

(52) U.S. Cl. CPC H01S 5/1021; H01S 5/02255; H01S 5/1092; H01S 5/0287

(57) ABSTRACT

In an embodiment a semiconductor laser includes a semiconductor body having a plurality of resonator regions, wherein the resonator regions are arranged side by side along a lateral direction, each resonator region having an active region configured to generate radiation, wherein the semiconductor body extends between two side faces, wherein the resonator regions are configured to emit laser radiation at one of the two side faces, and a layer sequence attached to at least one of the side faces, wherein the layer sequence forms at least part of a resonator mirror for at least one resonator region.

### CROSS-REFERENCE TO RELATED APPLICATIONS

This application is a national phase entry of PCT Application No. PCT/EP2021/082290, filed on Nov. 19, 2021, which claims priority to DE102020133174.6, filed Dec. 11, 2020, which applications are hereby incorporated herein by reference.

### TECHNICAL FIELD

The present application relates to a semiconductor laser and a method of producing a semiconductor laser.

### BACKGROUND

For example, for augmented reality applications, laser light sources are desired in which several emitters are arranged close to each other in order to be able to achieve improved resolution, frame rate and/or brightness. Particularly small distances between different emitters can be achieved if the emission regions are realized within a laser diode chip. However, it has been shown that disturbing image artifacts such as speckle can occur when the emission wavelengths of the emission regions are the same, which is typically the case when the emission regions are based on the same semiconductor layer sequence.

### SUMMARY

Embodiments provide multiple emission regions that have different emission wavelengths at close distances from each other.

A semiconductor laser having a semiconductor body is specified, wherein the semiconductor body has a plurality of resonator regions.

For example, the semiconductor body is formed by a semiconductor layer sequence based on a III-V compound semiconductor material.

III-V compound semiconductor materials are particularly suitable for radiation generation in the ultraviolet (Alₓ In_{y} Ga_{1-x-y} N) through the visible (Alₓ In_{y} Ga_{1-x-y} N, in particular for blue to green radiation, or Al In_{x y} Ga_{1-x-y} P, in particular for yellow to red radiation) to the infrared (Alₓ In_{y} Ga_{1-x-y} As) spectral range. Here, 0≤x≤1, 0≤y≤1 and x+y≤1, respectively, especially with x≠1, y≠1, x≠0 and/or y≠0. III-V compound semiconductor materials, especially those made of the aforementioned material systems, can further be used to achieve high internal quantum efficiencies in radiation generation.

The resonator regions are, for example, regions in which the laser radiation propagates in an index-guided manner, for example by structuring the semiconductor body into ridge waveguides. Alternatively or additionally, the resonator regions can also be regions in which the laser radiation propagates in a gain-guided manner. For example, the resonator regions are formed by energized regions of a planar semiconductor body.

For example, the resonator regions are arranged side by side along a lateral direction and each have an active region provided for generating radiation. In this context, a lateral direction is understood to be a direction that runs parallel to a main extension plane of the active region of the semiconductor body. For example, the lateral direction is perpendicular to the resonator axes of the resonator regions.

According to at least one embodiment of the semiconductor laser, the semiconductor body extends between two side faces. The side faces are arranged in particular on opposite sides and delimit the semiconductor body and in particular the resonator regions within the semiconductor body.

According to at least one embodiment of the semiconductor laser, laser radiation emerges from the resonator regions on one of the two side faces during operation of the semiconductor laser. For example, resonator mirrors are arranged at the two side faces, wherein typically one of the resonator mirrors has a high reflectivity, in particular a reflectivity of at least 95%, and the other resonator mirror, which serves as an output mirror, has a lower reflectivity in comparison. For example, the reflectivity at the output side is between 0.5% and 50% inclusive for the wavelength of maximum emission. For example, the laser radiation emerges from the individual resonator regions parallel to each other, i.e. along the same direction.

According to at least one embodiment of the semiconductor laser, a layer sequence is attached to at least one of the side faces. The layer sequence forms at least part of a resonator mirror for at least one resonator region. Suitable materials for the layer sequence are for example dielectric materials, in particular oxides, nitrides and fluorides such as for example SiO₂, SiN, Al₂O₃, TiO₂, Ta₂O₅ or MgF₂, or semiconductors such as Si, Ge or ZnSe in amorphous, crystalline or polycrystalline form.

The layer sequence may be attached to the side face of the semiconductor laser where the laser radiation exits during operation of the semiconductor laser or to the opposite side face of the semiconductor laser.

In particular, the layer sequence is a prefabricated element attached to one of the side faces of the semiconductor laser. For example, the layer sequence is deposited separately from the semiconductor laser on a substrate body and subsequently attached to the semiconductor laser. Thus, the layer sequence is not a coating of the semiconductor laser that is deposited directly onto the semiconductor laser by a deposition process.

In at least one embodiment of the semiconductor laser, the semiconductor laser comprises a semiconductor body having a plurality of resonator regions, the resonator regions being arranged side by side along a lateral direction and each having an active region provided for generating radiation. The semiconductor body extends between two side faces, wherein laser radiation emerges from the resonator regions at one of the two side faces during operation of the semiconductor laser. A layer sequence is attached to at least one of the side faces, which forms at least part of a resonator mirror for at least one resonator region.

The semiconductor laser thus has a layer sequence that is attached to the semiconductor body in a prefabricated form. During the production of the semiconductor laser, the layer sequence can thus be formed separately from the semiconductor laser and only subsequently attached to the semiconductor body of the semiconductor laser. At least one resonator mirror is thus formed by a layer sequence attached to the semiconductor laser. Via the layer sequence, the wavelength of maximum emission of the associated resonator region can be influenced, in particular also independently of the other resonator regions.

According to at least one embodiment of the semiconductor laser, the layer sequence has a plurality of subregions that are different from one another, with a subregion forming at least part of the resonator mirror associated with the resonator region for one of the resonator regions in each case. For example, the number of subregions of the layer sequence is equal to the number of resonator regions of the semiconductor body.

According to at least one embodiment of the semiconductor laser, the resonator mirrors formed by means of the subregions differ from each other with respect to their wavelength of maximum reflectivity. For example, the wavelengths of maximum reflectivity for at least two of the subregions differ from each other by at least 3 nm. For example, the wavelengths of maximum reflectivity for all subregions of the layer sequence differ from each other in pairs, in particular by at least 3 nm.

By means of the mutually different sub-regions, it can be achieved that the individual resonator regions of the semiconductor laser emit radiation with mutually different wavelengths of maximum emission, even if the active regions of the resonator regions are identical or at least identical within the scope of production tolerances related to lateral fluctuations in the epitaxial deposition of the semiconductor material of the semiconductor body.

The resonator regions can thus provide different wavelengths of maximum emission in a common semiconductor body. As a result, particularly small distances between the resonator regions can be achieved. For example, a center-to-center distance between adjacent resonator regions is between 5 μm and 500 μm inclusive.

This means that center-to-center distances can be achieved that would not be possible, or at least not easily achievable, with laser diode chips produced separately and subsequently placed next to each other.

According to at least one embodiment of the semiconductor laser, the wavelengths of maximum emission of at least two of the radiations emerging from the resonator regions differ from each other by at least 3 nm or at least 5 nm or at least 10 nm and/or by at most 15 nm or at most 20 nm. It has turned out that a difference in the wavelengths in this range can efficiently suppress speckle interference effects.

According to at least one embodiment of the semiconductor laser, the layer sequence is attached to a connection surface on the side face of the semiconductor body by a direct bond connection.

In a direct bond, the bond partners to be joined are attached to each other by atomic forces, for example van der Waals interactions and/or hydrogen bonds. A joining layer such as an adhesive layer is not required for this. Despite the absence of a joining layer, however, it is evident in the finished semiconductor laser that the layer sequence has been attached to the connection surface and has not been deposited on this surface by a deposition process.

According to at least one embodiment of the semiconductor laser, the connection surface is one of the side faces of the semiconductor laser. In this case, the layer sequence is thus directly attached to the side face of the semiconductor laser.

According to at least one embodiment of the semiconductor laser, the connection surface is formed by a coating applied to one of the side faces of the semiconductor laser. For example, the applied coating is a single-layer or multilayer coating. In particular, the coating may comprise the same material or at least the same type of material, for example an oxide, as the layer sequence. An attachment of the layer sequence to the connection surface may thus be simplified. The coating may form part of the resonator mirror. Further, the coating may be formed as a reflection reducing coating. For example, the coating extends continuously over several or even all resonator regions. Lateral structuring of the coating is therefore not required.

According to at least one embodiment of the semiconductor laser, the layer sequence is attached to one of the side faces of the semiconductor body by means of an adhesive layer. The layer sequence may be attached to the side face directly or indirectly, i.e. via at least one further element. The adhesive layer can be located, for example, over the entire surface or only in places between the side face of the semiconductor body and the layer sequence.

According to at least one embodiment of the semiconductor laser, an optical layer thickness of the adhesive layer is less than a quarter of the smallest wavelength of maximum emission of radiation emitted from the resonator regions in the material of the adhesive layer during operation of the semiconductor laser. For example, the optical layer thickness is at most 50% or at most 20% of a quarter of the smallest wavelength of maximum emission. Such a small layer thickness of the adhesive layer can minimize the influence of the beam divergence on the effective reflectivity. This makes the optical properties of the semiconductor laser less dependent on variations in the thickness of the adhesive layer due to the production. Deviating from this, however, larger layer thicknesses of the adhesive layer can also be applied.

According to at least one embodiment of the semiconductor laser, the adhesive layer is applied to a coating of a side face of the semiconductor laser. For example, the coating is a reflection reducing coating. For example, the coating has a reflectivity of at most 1%, in particular for a wavelength of maximum emission. For example, the coating is applied to an output side of the semiconductor body. This is favorable to reduce the influence of the thickness of the adhesive layer on the effective reflectivity of the semiconductor laser and thus its optical properties.

According to at least one embodiment of the semiconductor laser, the layer sequence is attached to one of the side faces of the semiconductor body via a spacer. Thus, between the layer sequence and the side face of the semiconductor body there may be a gap which is free of solid matter, for example a gap filled with a gas, such as air.

The width of the gap, i.e. the extent along the resonator axis, is, for example, less than a quarter of the smallest wavelength of maximum emission of the radiation emitted by the resonator regions in the gap.

Such a spacer can be used to reliably predefine the distance between the layer sequence and the side face of the semiconductor body.

According to at least one embodiment of the semiconductor laser, the layer sequence is arranged on a substrate body. The substrate body is, for example, the body on which the layer sequence is deposited. If the layer sequence forms the resonator mirror at which the radiation emerges from the semiconductor laser, the substrate body is expediently transmissive for the radiation of the semiconductor laser. For example, a glass or semiconductor material that is transmissive in the wavelength range of the emitted radiation of the semiconductor laser is suitable for a radiation-transmissive substrate body.

If the layer sequence forms the resonator mirror opposite the output side, the substrate body can also be opaque to the generated radiation. In this case, for example, silicon or another semiconductor material with a comparatively small band gap is also suitable.

According to at least one embodiment of the semiconductor laser, the substrate body comprises a reflection reducing coating on a radiation exit surface. By means of the reflection reducing coating, it can be avoided that an unwanted radiation component is coupled back into the resonator regions of the semiconductor laser. Viewed along the beam path, the layer sequence and the reflection reducing coating are located at opposite ends of the optical path through the substrate body.

According to at least one embodiment of the semiconductor laser, the substrate body has a deflection surface at which the radiation emerging from one of the side faces of the semiconductor laser is deflected. After the deflection, a main radiation direction of the semiconductor laser has an angle different from 0° with respect to the main extension plane of the active region, for example an angle between 10° and 170° inclusive, approximately an angle between 80° and 100° inclusive, for example 90°.

For example, the semiconductor laser can thus act as a surface emitter, although unlike a vertical cavity surface emitting laser (VCSEL), the radiation propagating in the semiconductor laser oscillates along the main extension plane of the active region and emerges laterally from the semiconductor body.

For example, the semiconductor laser described is particularly suitable for applications where multiple emission regions are required in close proximity to each other, such as laser beam scanners in augmented reality applications.

Furthermore, a method of producing a semiconductor laser is specified.

According to at least one embodiment of the method, a semiconductor body is provided having a plurality of resonator regions, the resonator regions being arranged side by side along a lateral direction and each having an active region provided for generating radiation. A layer sequence is formed on a substrate body. The layer sequence is attached to a side face of the semiconductor body, wherein the layer sequence forms at least a part of a resonator mirror for at least one resonator region.

Thus, the layer sequence is formed separately from the semiconductor body on a separate substrate body, for example by a deposition process, such as a chemical vapor deposition (CVD) or physical vapor deposition (PVD) process. For example, sputtering, vapor deposition or an epitaxy process such as molecular beam epitaxy (MBE) or chemical beam epitaxy (CBE) are suitable. The layer sequence thus prefabricated can be attached to the semiconductor body. In particular, when forming the layer sequence, subregions of the layer sequence that are different from each other can be formed, for example, by lithographically patterning the layer sequence. Such a structuring is easier and more reliable to realize on a substrate body than on a side face of a semiconductor laser.

According to at least one embodiment of the method, the layer sequence is attached to the side face by a direct bond. This can be promoted by an action of pressure and/or temperature.

According to at least one embodiment of the method, the substrate body is removed. In particular, the substrate body may be removed even before the layer sequence is attached to the side face of the semiconductor laser. For example, the layer sequence is pressed to the semiconductor laser by means of a transfer process.

The described method is particularly suitable for producing a semiconductor laser described above. Features specified in connection with the semiconductor laser can therefore also be used for the method and vice versa.

Further configurations and expediencies will be apparent from the following description of the exemplary embodiments in conjunction with the figures.

### BRIEF DESCRIPTION OF THE DRAWINGS

FIGS. 1A to 1C show an exemplary embodiment of a semiconductor laser, where FIG. 4A is a schematic sectional view and FIG. 1B is a schematic top view. FIG. 1C schematically shows an example of a spectral curve of the reflectivity product R formed by the product of the reflectivities of the resonator mirrors;

FIGS. 2A and 2B show an exemplary embodiment of a semiconductor laser in schematic sectional view (FIG. 2A) and in plan view (FIG. 2B);

FIGS. 3A and 3B show an exemplary embodiment of a semiconductor laser in schematic sectional view (FIG. 3A) and in plan view (FIG. 3B);

FIG. 4 shows an exemplary embodiment of a semiconductor laser in schematic sectional view;

FIG. 5 shows an exemplary embodiment of a semiconductor laser in schematic sectional view;

FIG. 6 shows an exemplary embodiment of a semiconductor laser in schematic sectional view;

FIG. 7 shows an exemplary embodiment of a semiconductor laser in schematic sectional view;

FIG. 8 an exemplary embodiment of a semiconductor laser in schematic sectional view; and

FIGS. 9A to 9C show an exemplary embodiment of a method of producing a semiconductor laser by means of intermediate steps shown in schematic plan view in FIGS. 9A and 9C and in a sectional view through the substrate body in FIG. 9B.

Identical, similar or similarly acting elements are given the same reference signs in the figures.

The figures are each schematic representations and therefore not necessarily to scale. Rather, individual elements and in particular layer thicknesses may be shown exaggeratedly large for improved representation and/or better understanding.

### DETAILED DESCRIPTION OF ILLUSTRATIVE EMBODIMENTS

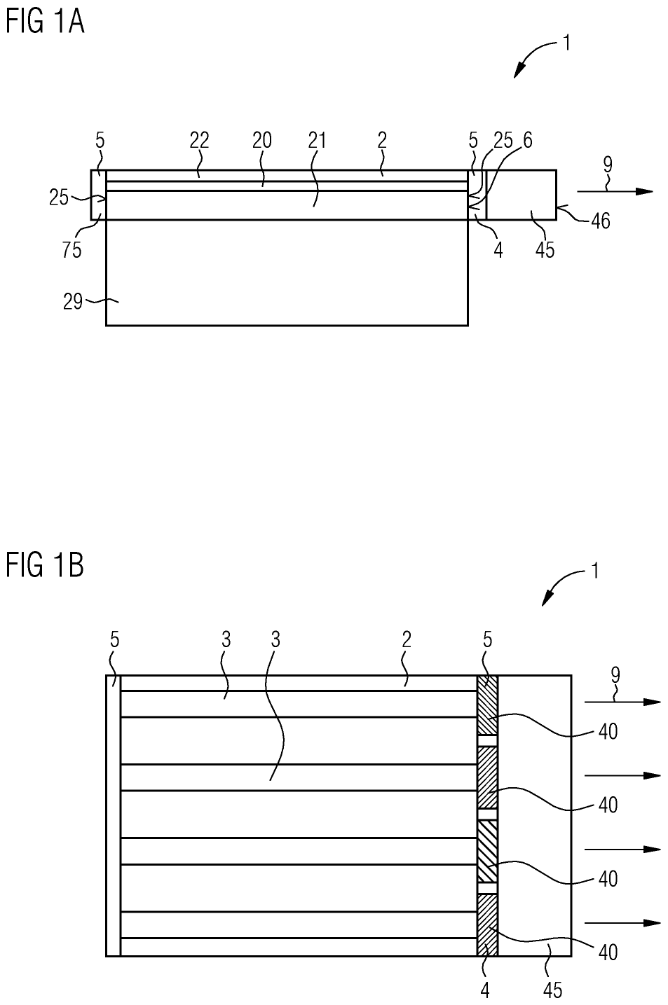

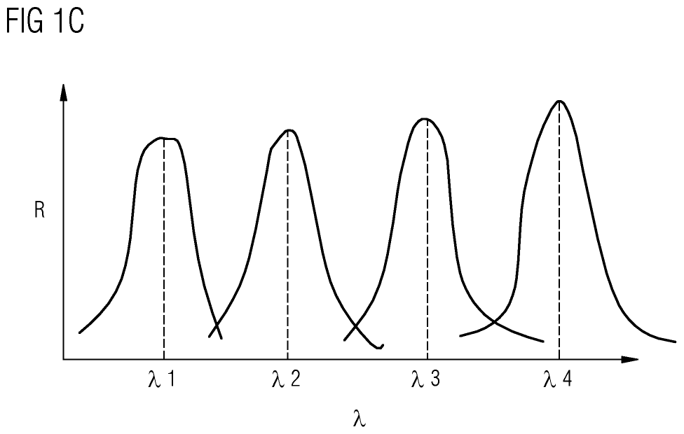

In the embodiments shown in FIGS. 1A and 1B, the semiconductor laser 1 has a semiconductor body 2 with a plurality of resonator regions 3. In the exemplary embodiment shown, the semiconductor laser 1 has four resonator regions 3. However, the number of resonator regions may vary within wide limits. For example, the number of resonator regions 3 ranges from 2 inclusive to 20 inclusive.

The resonator regions 3 are arranged adjacent to each other along a lateral direction, and each has an active region 20 provided for generating radiation. The active region 20 is arranged between a first semiconductor layer 21 of a first conductivity type and a second semiconductor layer 22 of a second conductivity type different from the first conductivity type, so that the active region 20 is in a pn junction. For example, the first semiconductor layer 21 is n-type and the second semiconductor layer 22 is p-type. The first semiconductor layer 21, the second semiconductor layer 22, and the active region 20 are typically each formed in multiple layers. For example, the active region 20 has a quantum structure with one or more quantum wells.

This is not explicitly shown for simplified illustration. Furthermore, electrical contact surfaces or contact layers for electrical contacting of the semiconductor laser 1 are also not shown.

The semiconductor body 2 is arranged on a carrier 29, for example a growth substrate for the epitaxial deposition of the semiconductor layers of the semiconductor body 2. However, the carrier 29 may also be different from the growth substrate and may be attached to the semiconductor body 2 by wafer bonding, for example, during the production of the semiconductor laser 1.

The semiconductor body 2 extends between two opposite side faces 25, which delimit the semiconductor body 2 in the lateral direction. During operation of the semiconductor laser 1, laser radiation emerges from the resonator regions 3 at one of the two side faces 25. This is illustrated by arrows 9 in FIGS. 1A and 1B, respectively.

A layer sequence 4 is attached to one of the side faces 25, in the embodiment shown, the side face 25 where the laser radiation exits the semiconductor laser 1. The layer sequence 4 has a plurality of subregions 40. The subregions 40 are different from each other, wherein one subregion 40 is provided for each of the resonator regions 3 and forms the resonator mirror 5 for the respective resonator region 3.

On the opposite side face 25, the resonator mirror 5 is formed by a highly reflective coating 75. For example, the highly reflective coating has a reflectivity of at least 95%, for example 99% or more, for the laser radiation to be generated by the semiconductor laser.

The layer sequence 4 is formed, for example, by a sequence of several layers, for example oxide layers and/or nitride layers, with adjacent layers each having different refractive indices from one another, so that a Bragg mirror is formed. The subregions 40 of the layer sequence differ from each other with respect to their wavelength of maximum reflectivity. This is shown schematically in FIG. 1C. Here, the spectral variation of the reflectivity product R from the reflectivity of the two resonator mirrors 5 is shown schematically for each of the four subregions 40. The spectral difference of this reflectivity product R results in particular from the different design of the subregions 40. For this purpose, the subregions 40 can differ from each other with respect to the layer thicknesses, the materials and/or the number of layers.

The highly reflective coating 75 forming the opposite resonator mirror 5 can be the same for all resonator regions 3. By means of the subregions 40 differing from each other with respect to their wavelength of maximum reflectivity λ1, λ2, λ3, λ4, it can be achieved that the resonator regions 3 have different wavelengths of maximum emission from each other. For example, the difference for at least two of the resonator regions 3 is between 3 nm and 20 nm inclusive. These different wavelengths of maximum reflectivity cause corresponding different wavelengths of maximum emission of the semiconductor laser 1. As schematically shown in FIG. 1C, the wavelengths of maximum reflectivity and thus the wavelengths of maximum emission for all semiconductor lasers may differ from each other in pairs.

The subregions 40 of the layer sequence 4 can alternatively or additionally be formed in such a way that the radiation emitted by the associated resonator regions 3 differs in polarization for at least two resonator regions. For example, the polarizations of the radiation emitted by adjacent resonator regions 3 can be oriented perpendicular to each other. This can further reduce artifacts caused by closely spaced emission regions.

In the exemplary embodiment shown in FIGS. 1A and 1B, the layer sequence 4 is attached to the side face of the semiconductor body 2 by a direct bond connection to a connection surface 6. Here, the connection surface 6 is the side face 25 of the semiconductor body. Thus, the layer sequence 4 is directly adjacent to the side face 25 of the semiconductor body 2. Thus, although the active regions 20 of the resonator regions 3 are at least nominally not different from each other, the individual resonator regions 3 each emit radiation at different wavelengths of maximum emission from each other. Resonator regions 3 with different wavelengths of maximum emission can therefore be integrated in a common semiconductor body 2. Thus, small distances between the resonator regions 3 can be achieved, especially compared to individual semiconductor chips placed side by side.

In the exemplary embodiment shown in FIGS. 1A and 1B, the layer sequence 4 is arranged on a substrate body 45. The substrate body 45 forms a radiation exit surface 46 of the semiconductor laser. The substrate body 45 is expediently transmissive to the radiation generated by the semiconductor laser 1. However, the substrate body 45 may also be opaque to the radiation generated by the semiconductor laser 1 if the layer sequence 4 does not form the resonator mirror 5 at which the radiation is emitted during operation of the semiconductor laser, but forms the opposite resonator mirror 5.

The semiconductor body 2 comprises, for example, a III-V compound semiconductor material. The radiation to be generated is, for example, in the ultraviolet, visible or infrared spectral range.

For the formation of the resonator regions 3, for example, a structuring of the semiconductor bodies into ridge waveguides or a planar design of the semiconductor laser 1 is suitable, in which the radiation propagating in the resonator region 3 is gain-guided in the lateral direction.

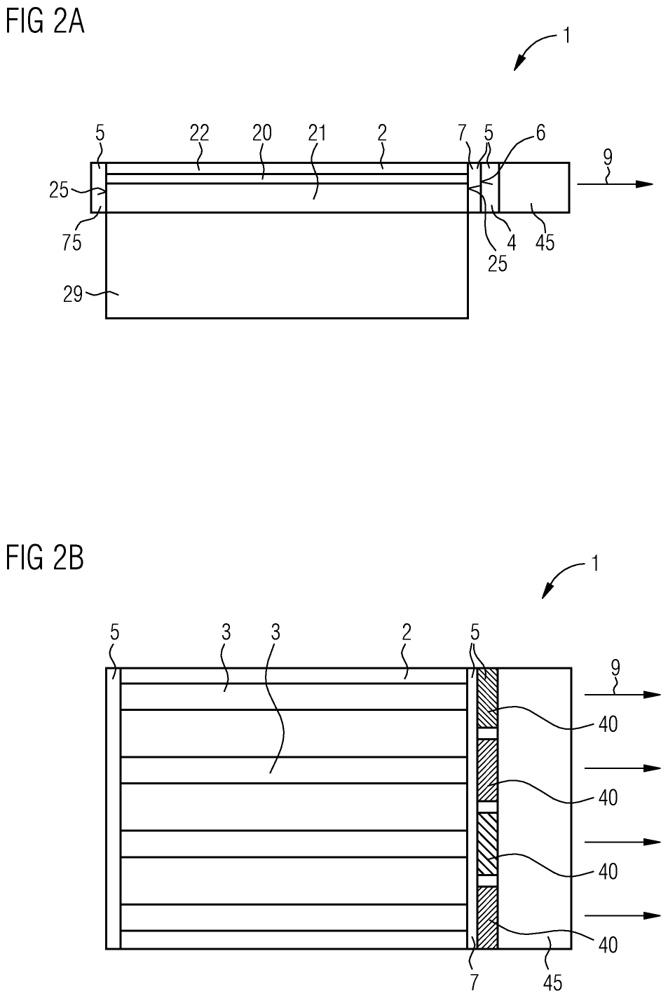

The exemplary embodiment shown in FIGS. 2A and 2B is substantially the same as the exemplary embodiment described in connection with FIGS. 1A and 1B. In contrast, the connection surface 6 is formed by a coating 7 of a side face 25 of the semiconductor laser 1. The coating 7 may form resonator mirrors 5 for the resonator regions 3 together with the layer sequence 4, respectively. The coating 7 extends continuously over adjacent resonator regions 3, in particular over all resonator regions 3 of one semiconductor laser 1. Thus, no lateral structuring of the coating 7 is required when creating the coating 7. Suitable materials for the coating 7 are, for example, those indicated in connection with the layer sequence 4, for example a dielectric material, such as an oxide. The direct bond connection at the connection surface 6 can be made between two layers of the same material type, for example between two oxide layers. A direct bond connection can thus be formed particularly reliably.

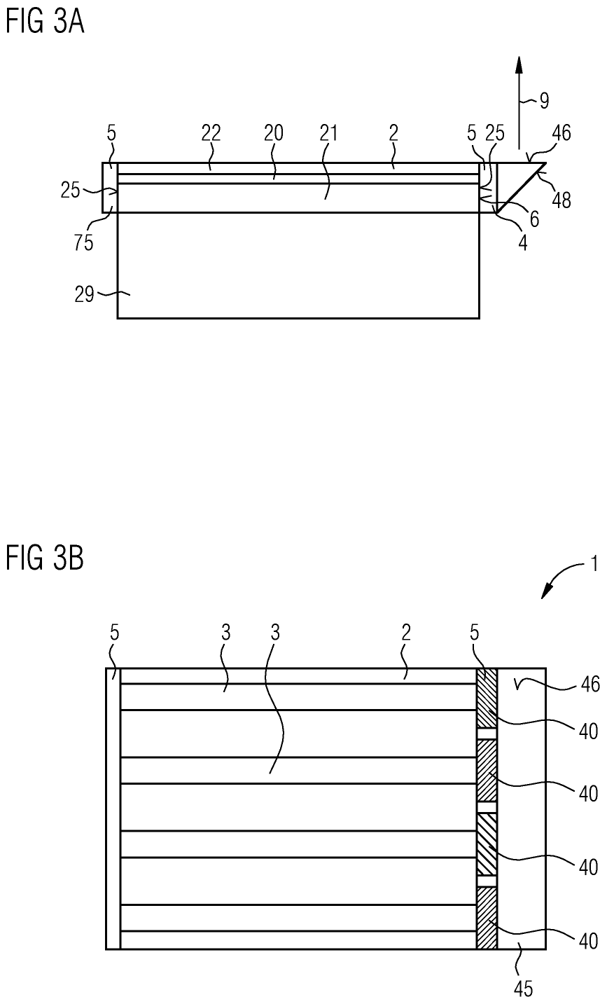

The exemplary embodiment illustrated in FIGS. 3A and 3B is substantially the same as the exemplary embodiment described in connection with FIGS. 1A and 1B. In contrast, the substrate body 45 has a deflection surface 48. At the deflection surface 48, radiation emerging from the semiconductor body 2 and coupled into the substrate body 45 is deflected so that a main radiation direction of the semiconductor laser is arranged at an angle to the main extension plane of the active region 20. In the exemplary embodiment shown in FIGS. 3A and 3B, the angle is 90° so that the semiconductor laser radiates perpendicularly to the main extension plane of the active region 20. Thus, the radiation exit surface 46 is parallel to the main extension plane of the active region 20 of the semiconductor 1. However, other radiation angles can be set.

In the exemplary embodiment shown in FIG. 3A, the reflection at the deflection surface 48 takes place by total reflection at the deflection surface 48. Deviating from this, however, a reflective layer, for example a metal layer or a Bragg mirror, can also be arranged at the deflection surface 48.

Such a deflection surface may also be applied in the exemplary embodiments according to FIGS. 2A and 2B, 4, 5, 6 and 7.

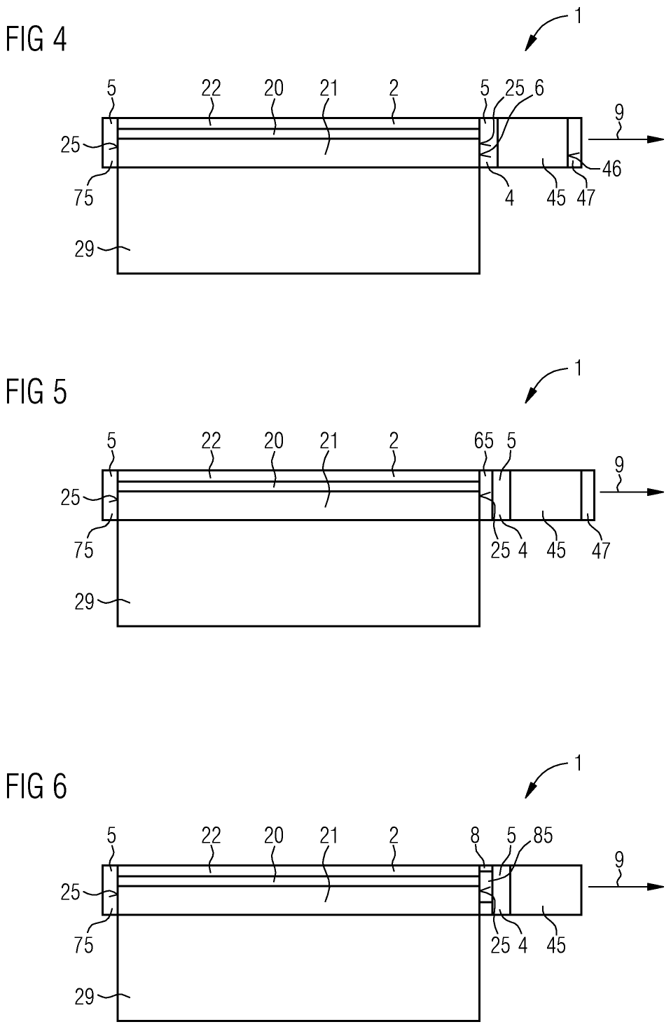

The exemplary embodiment shown in FIG. 4 is essentially the same as the exemplary embodiment described in connection with FIGS. 1A and 1B. In contrast, the radiation exit surface 46 of the substrate body 45 has a reflection reducing coating 47. By means of the reflection reducing coating, the radiation portion that could be reflected at the radiation exit surface 46 and thus coupled back into the semiconductor body 2 can be minimized.

Such a reflection reducing coating 47 may also be applied to the other exemplary embodiments having a substrate body 45.

The exemplary embodiment shown in FIG. 5 is substantially the same as the exemplary embodiment shown in connection with FIGS. 1A and 1B.

In contrast, the layer sequence 4 is attached to a side face 25 of the semiconductor body 2 by means of an adhesive layer 65. A layer thickness of the adhesive layer 65 is preferably small with respect to the wavelength of the radiation to be emitted from the semiconductor laser, so that the adhesive layer 65 does not have a significant disturbing influence on the resonator between the resonator surfaces 5. For example, a layer thickness of the adhesive layer is between 10 nm and 40 nm inclusive.

The adhesive layer 65 may also be applied to a coating 7 of the side face 25 (see FIG. 2A). For example, the coating 7 is a reflection reducing coating. For example, the reflectivity for the wavelength of maximum emission of the radiation emitted by the semiconductor laser 1 is at most 1%. This can further reduce the influence of the adhesive layer 65 on the optical properties of the semiconductor laser 1.

Furthermore, the semiconductor laser 1 shown in FIG. 5 has a reflection reducing coating 47 on the radiation exit surface 46 of the substrate body 45 as described in connection with FIG. 4. However, such a reflection reducing coating 47 is not absolutely necessary.

The exemplary embodiment shown in FIG. 6 corresponds essentially to the exemplary embodiment described in connection with FIGS. 1A and 1B. In contrast, a spacer 8 is arranged between the side face 25 of the semiconductor body 2 and the layer sequence 4. The layer sequence 4 is attached to the side face 25 via the spacer 8. As described above, the attachment can be made via a direct bonding connection or an adhesive layer.

A gap 85 is formed between the side face 25 and the layer sequence 4. The gap 85 is free of solid material and is filled, for example, by a gas, such as air. The width of the gap 85, i.e. the extent along the main radiation direction of the radiation, is expediently small compared to the wavelength of the radiation to be generated by the semiconductor laser. Thus, the reflection at the side face 25, i.e. the interface to the gap 85, can be reduced. If the spacer 8 is attached via an adhesive layer 65, the adhesive bond can be formed in such a way that the radiation does not have to be coupled out of the semiconductor laser through the adhesive layer.

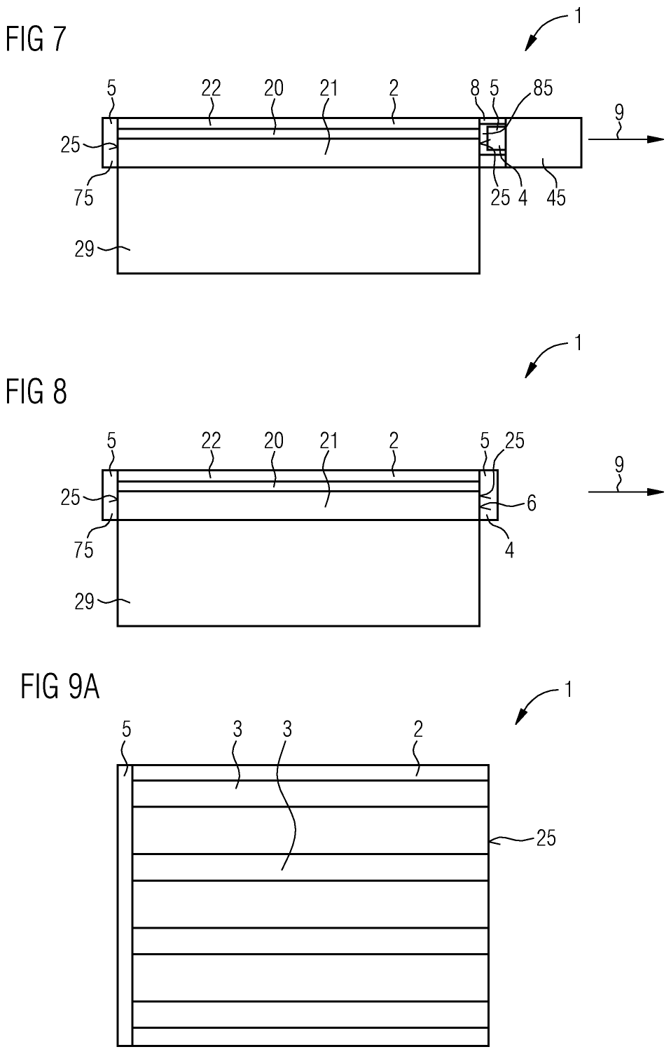

The exemplary embodiment shown in FIG. 7 corresponds essentially to the exemplary embodiment described in connection with FIG. 6. In contrast, the spacer 8 is arranged to the side of the layer sequence 4. The spacer 8 and the layer sequence 4 are thus located next to each other on the substrate body 45. The layer sequence 4 is thus attached to the side face 25 via the substrate body 45.

The exemplary embodiment shown in FIG. 8 corresponds essentially to the exemplary embodiment described in connection with FIGS. 1A and 1B. In contrast, the semiconductor laser 1 is free of a substrate body 45 of the layer sequence 4. In this case, therefore, the layer sequence 4 itself forms the radiation exit surface of the semiconductor laser 1 when the layer sequence 4 forms the resonator mirror 5 at which the radiation is emitted during operation of the semiconductor laser 1.

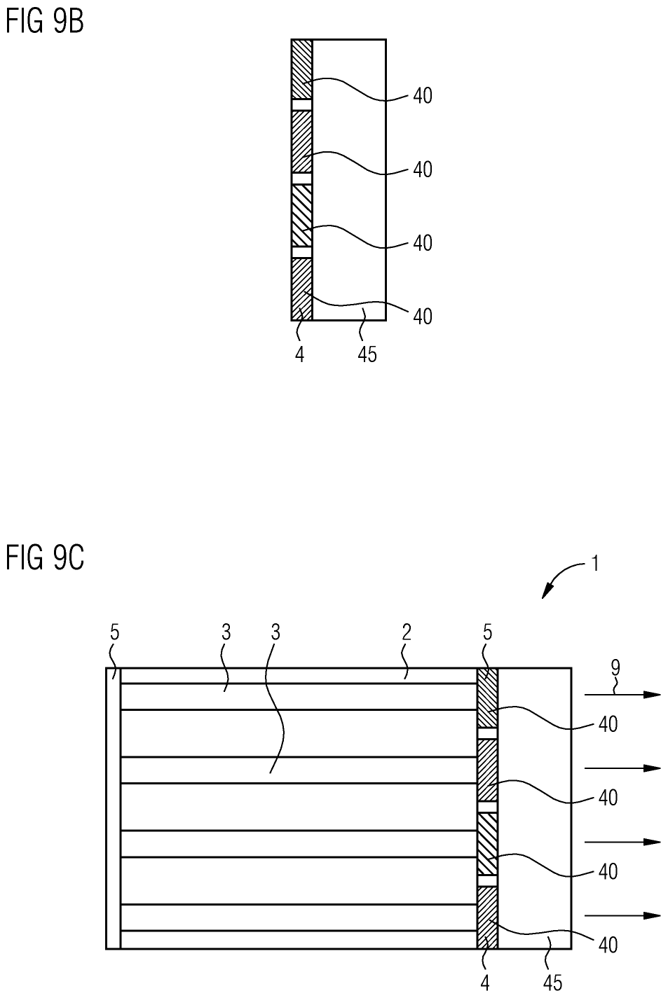

FIGS. 9A to 9C describe an exemplary embodiment of a method for producing a semiconductor laser 1.

As shown in FIG. 9A, a semiconductor body 2 is provided, the semiconductor body having a plurality of resonator regions, the resonator regions 3 being arranged side by side along a lateral direction and each having an active region 20 provided for generating radiation (compare FIG. 1B).

FIG. 9B illustrates a layer sequence 4 that has been formed on a substrate body 45. For example, the layer sequences can be deposited by a PVD process and/or a CVD process and subsequently patterned. The deposition of dielectric layers and the patterning can also be repeated several times.

The subregions 40 are formed on the substrate body 45 with a center-to-center distance corresponding to the center-to-center distance of the resonator regions 3 of the semiconductor body 2 to which the layer sequence 4 is attached in a subsequent production step.

FIG. 9C illustrates the completed semiconductor laser 1 with the layer sequence 4 attached to a side face 25 of the semiconductor body 2, wherein the layer sequence 4 forms at least part of a resonator mirror 5 for at least one resonator region, in the exemplary embodiment shown for each of the four resonator regions.

The method is exemplified by the production of a semiconductor laser 1 formed as described in connection with FIGS. 1A and 1B.

However, the method can also be modified to produce the semiconductor lasers 1 described in connection with the other exemplary embodiments or other semiconductor lasers. For example, the layer sequence 4 may be attached to the side face 25 of the semiconductor body 2 by an adhesive layer instead of by a direct bond. Further, the substrate body 45 may be removed, for example, even before the layer sequence 4 is attached to the side face 25 of the semiconductor body 2.

The substrate-less layer sequence 4 can be pressed against the side face 25 by a transfer process, for example.

With the described method, a layer sequence 4 can be formed separately from the semiconductor bodies 2 of the semiconductor laser 1, which has different reflection profiles for individual resonator regions 3 of the semiconductor laser 1. The reflection profiles can be checked even before they are attached to the semiconductor laser. Furthermore, minor deviations in the emission wavelength of the semiconductor laser can be made by adjusting the separately produced layer sequence without having to change the production of the semiconductor body 2 per se.

The invention is not limited by the description based on the exemplary embodiments. Rather, the invention encompasses any new feature as well as any combination of features, which in particular includes any combination of features in the patent claims, even if this feature or combination itself is not explicitly stated in the patent claims or exemplary embodiments.

1-19. (canceled)

20. A semiconductor laser comprising:
a semiconductor body having a plurality of resonator regions,
wherein the resonator regions are arranged side by side along a lateral direction, each resonator region having an active region configured to generate radiation,
wherein the semiconductor body extends between two side faces,
wherein the resonator regions are configured to emit laser radiation at one of the two side faces; and
a layer sequence attached to at least one of the side faces,
wherein the layer sequence forms at least part of a resonator mirror for at least one resonator region.

21. The semiconductor laser according to claim 20,
wherein the layer sequence comprises a plurality of subregions, which are different from one another, and
wherein a subregion in each case forms, for one of the resonator regions, at least part of the resonator mirror associated with the at least one resonator region.

22. The semiconductor laser according to claim 21, wherein resonator mirrors formed by the subregions differ from each other with respect to their wavelength of maximum reflectivity.

23. The semiconductor laser according to claim 20, wherein the wavelengths of maximum emission of at least two of the radiations emittable from the resonator regions differ from each other by at least 3 nm and by at most 20 nm.

24. The semiconductor laser according to claim 20, wherein the layer sequence is attached by a direct bond connection to a connection surface on the side face of the semiconductor body.

25. The semiconductor laser according to claim 24, wherein the connection surface is one of the side faces of the semiconductor laser.

26. The semiconductor laser according to claim 25, wherein the connection surface is formed by a coating applied to one of the side faces of the semiconductor laser.

27. The semiconductor laser according to claim 20, wherein the layer sequence is attached to one of the side faces of the semiconductor body by an adhesive layer.

28. The semiconductor laser according to claim 27, wherein the adhesive layer is applied to a coating of a side face of the semiconductor laser.

29. The semiconductor laser according to claim 28, wherein the coating is applied to an output side of the semiconductor body and has a reflectivity of at most 1%.

30. The semiconductor laser according to claim 27, wherein an optical layer thickness of the adhesive layer is smaller than a quarter of the smallest wavelength of maximum emission of the radiation emittable from the resonator regions in a material of the adhesive layer.

31. The semiconductor laser according to claim 20, wherein the layer sequence is attached to one of the side faces of the semiconductor body via a spacer.

32. The semiconductor laser according to claim 20, wherein the layer sequence is arranged on a substrate body.

33. The semiconductor laser according to claim 32, wherein the substrate body comprises a reflection reducing coating on a radiation exit surface.

34. The semiconductor laser according to claim 32, wherein the substrate body has a deflection surface configured to deflect the radiation emerging from one of the side faces of the semiconductor laser.

35. A method for producing a semiconductor laser, the method comprising:
providing a semiconductor body having a plurality of resonator regions, the resonator regions being arranged side by side along a lateral direction and each resonator region having an active region for generating radiation;
forming a dielectric layer sequence on a substrate body; and
attaching the dielectric layer sequence to a side face of the semiconductor body,
wherein the dielectric layer sequence for at least one resonator region forms at least part of a resonator mirror.

36. The method according to claim 35, wherein the layer sequence is attached to the side face by a direct bond connection.

37. The method according to claim 35, further comprising removing the substrate body.
